(19) United States
(12) Patent Application Publication
(10) Pub. No.: US 2019/0013083 A1
(43) Pub. Date: Jan. 10, 2019

(54) SHIFT REGISTER UNIT AND GATE SCANNING CIRCUIT

(71) Applicants: BOE TECHNOLOGY GROUP CO., LTD., Beijing (CN); Ordos Yuansheng Optoelectronics Co., Ltd., Ordos, Inner Mongolia (CN)

(72) Inventors: Jiguo Wang, Beijing (CN); Fuqiang Li, Beijing (CN)

(21) Appl. No.: 15/749,361

(22) PCT Filed: Jul. 18, 2017
(86) PCT No.: PCT/CN2017/093354

§ 371 Date: Jan. 31, 2018

(30) Foreign Application Priority Data
Sep. 5, 2016 (CN) 201610802114.7

(51) Int. Cl. G11C 19/28; G09G 3/20

(52) U.S. Cl. CPC G11C 19/287; G09G 3/20; G09G 2300/0809; G09G 2310/0286; G09G 2310/08

(57) ABSTRACT

The present disclosure provides a shift register unit and a gate scanning circuit. In the shift register unit, when a first scanning pulse inputting terminal is at a first level, a voltage at a first node is pulled by a first DC voltage terminal; when a second scanning pulse inputting terminal is at the first level, the voltage at a first node is pulled by a second DC voltage terminal. In addition, each stage of the shift register unit have two scanning pulse outputting terminal. In a next period after the first scanning pulse outputting terminal outputs gate driving signals to the Nth row of pixel units, the second scanning pulse outputting terminal may output gate voltages to the (N+1)th row of pixel units.

### CROSS-REFERENCE TO RELATED APPLICATION(S)

This application is a Section 371 National Stage Application of International Application No. PCT/CN2017/093354 filed on Jul. 18, 2017, which in turn claims the priority of Chinese Patent Application No. 201610802114.7 filed on Sep. 5, 2016, the disclosure of which is incorporated herein by reference in its entirety.

### TECHNICAL FIELD

Embodiments of the present invention relate to the field of display technology, and in particular, to a shift register unit and a gate scanning circuit.

### BACKGROUND

GOA (Gate Driver on Array) is an important means for narrowing display devices. A gate driving circuit integrated into an array substrate is composed of a plurality of stages of shift register units. Each stage of shift register units sequentially shifts and outputs a scanning pulse to gates of thin film transistors in each row of pixel units, so that the corresponding thin film transistor can be turned on, realizing the driving process of each row of pixel units.

For each stage of shift register unit, its outputted scanning pulse is used as an input for a next stage of shift register unit, so as to provide an initial voltage for the next stage of shift register unit. That is to say, the conventional gate driving circuit realizes a forward scanning from G (1) to G (N).

However, in practicality, the forward scanning may cause device losses in the first few stages of the shift register units and reduce the life of the display panel. In addition, when the gate driving circuit scans the gate lines, the displaying points of each row of liquid crystal units in the TFT panel can be sequentially turned on, and only one row of the liquid crystal units is turned on at a time until the last row of liquid crystal units in the TFT panel is turned on. After then, the turning on process is repeated from the displaying point of the first row of liquid crystal units in the TFT panel. However, this displaying method has a poor flexibility of displaying, and cannot meet a variety of display requirements.

### SUMMARY

In view of that, embodiments of the present disclosure provide a shift register unit and a gate scanning circuit.

According to a first aspect of embodiments of the present disclosure, there is provided a shift register unit, comprising:

an inputting sub-circuit, electrically connected to a first DC voltage terminal, a second DC voltage terminal, a third DC voltage terminal, a first scanning pulse inputting terminal, a second scanning pulse inputting terminal and a first node, and configured to conduct the first node with the first DC voltage terminal in response to the first scanning pulse inputting terminal being a first level, and to conduct the first node with the second DC voltage terminal in response to the second scanning pulse inputting terminal being the first level;

a first energy storage sub-circuit, electrically connected to the first node and configured to maintain the charge of the first node when the first node is floating;

a second energy storage sub-circuit, electrically connected to a third node and configured to maintain the charge of the third node when the third node is floating;

a first outputting sub-circuit, electrically connected to the first node, a first clock signal terminal and a first scanning pulse outputting terminal, and configured to conduct the first scanning pulse outputting terminal with the first clock signal terminal in response to the first node being the first level;

a second outputting sub-circuit, electrically connected to the first node, a second clock signal terminal and a second scanning pulse outputting terminal, and configured to conduct the second scanning pulse outputting terminal with the second clock signal terminal in response to the first node being the first level;

a restoring sub-circuit, electrically connected to the first node, the third node, a fourth DC voltage terminal, the first scanning pulse outputting terminal and the second scanning pulse outputting terminal; and configured to conduct the first node, the first scanning pulse outputting terminal, the second scanning pulse outputting terminal and the fourth DC voltage terminal in response to the third node being at the first level;

a level controlling sub-circuit for the third node, electrically connected to the third DC voltage terminal, the fourth DC voltage terminal, the first node, the third node, and a fourth node, and configured to conduct the third node with the third DC voltage terminal in response to the fourth node being at the first level, and to conduct the third node with the fourth DC voltage terminal in response to the first node being at the first level; and

a level controlling sub-circuit for the fourth node, electrically connected to the first DC voltage terminal, the second DC voltage terminal, a third clock signal terminal and the fourth node, and configured to conduct the fourth node with the third clock signal terminal in response to the first DC voltage terminal being the first level, and to conduct the fourth node with the third clock signal terminal in response to the second DC voltage terminal being the first level.

For example, the shift register unit may further comprise:

a resetting sub-circuit, electrically connected to the third node, a resetting enable controlling terminal, the third DC voltage terminal, the fourth DC voltage terminal, the first scanning pulse outputting terminal and the second scanning pulse outputting terminal, and configured to conduct the third node with the fourth DC voltage terminal, and conduct the first and second scanning pulse outputting terminals with the third DC voltage terminal, in response to the resetting enable controlling terminal being at the first level.

For example, the resetting sub-circuit comprises a first transistor, a second transistor, and a third transistor, and

the first transistor has a gate connected to the resetting enable controlling terminal, one of a source and a drain connected to the fourth DC voltage terminal, and the other connected to the third node;

the second transistor has a gate connected to the resetting enable controlling terminal, one of a source and a drain connected to the third DC voltage terminal, and the other connected to the first scanning pulse outputting terminal; and

the third transistor has a gate connected to the resetting enable controlling terminal, one of a source and a drain connected to the third DC voltage terminal, and the other connected to the second scanning pulse outputting terminal.

For example, the inputting sub-circuit comprises a fourth transistor, a fifth transistor and a transmission sub-circuit, and the fourth transistor has a gate connected to the first scanning pulse inputting terminal, one of a source and a drain connected to the first DC voltage terminal, and the other connected to the first node;

the fifth transistor has a gate connected to the second scanning pulse inputting terminal, one of a source and a drain connected to the first DC voltage terminal, and the other connected to the first node; and

the transmission sub-circuit comprises a sixth transistor having a gate connected to the third DC voltage terminal, one of a source and a drain connected to the second node, and the other connected to the first node.

For example, the first energy storage sub-circuit comprises a first capacitor having one terminal connected to the first node and the other connected to the fourth DC voltage terminal; and/or the second energy storage sub-circuit comprises a second capacitor having one terminal connected to the third node and the other connected to the fourth DC voltage terminal.

For example, the first outputting sub-circuit comprises a seventh transistor having a gate connected to the first node, one of a source and a drain connected to the first scanning pulse outputting terminal, and the other connected to the first clock signal terminal; and/or

the second outputting sub-circuit comprises an eighth transistor having a gate connected to the first node, one of a source and a drain connected to the second scanning pulse outputting terminal, and the other connected to the second clock signal terminal.

For example, the restoring sub-circuit comprises:

a ninth transistor, a tenth transistor and an eleventh transistor;

the ninth transistor has a gate connected to the third node, one of a source and a drain is connected to the first node, and the other connected to the fourth DC voltage terminal;

the tenth transistor has a gate connected to the third node, one of a source and a drain is connected to the first scanning pulse outputting terminal, and the other connected to the fourth DC voltage terminal; and

the eleventh transistor has a gate connected to the third node, one of a source and a drain connected to the second scanning pulse outputting terminal, and the other connected to the fourth DC voltage terminal.

For example, the level controlling sub-circuit for the third node comprises a fourteenth transistor and a fifteenth transistor, wherein,

the fourteenth transistor has a gate connected to the fourth node, one of a source and a drain connected to the third DC voltage terminal, and the other connected to the third node;

the fifteenth transistor has a gate connected to the first node, one of a source and a drain connected to the fourth DC voltage terminal, and the other connected to the third node.

For example, the level controlling sub-circuit for the fourth node comprises a twelfth transistor and a thirteenth transistor, wherein,

the twelfth transistor has a gate connected to the first DC voltage terminal, one of a source and a drain connected to the third clock signal terminal, and the other connected to the fourth node; and

the thirteenth transistor has a gate connected to the second DC voltage terminal, one of a source and a drain connected to the third clock signal terminal, and the other connected to the fourth node.

For example, the first level is a high level.

According to a second aspect of embodiments of the present disclosure, there is provided gate driving circuit, comprising a plurality of cascaded shift register units and a plurality of clock signal lines, wherein each of the plurality of the cascaded shift register units is the shift register unit of the present disclosure;

wherein for adjacent two shift register units of the plurality of cascaded shift register units, a shift register unit of a previous stage of the adjacent two shift register units has its second scanning pulse outputting terminal connected to the first scanning pulse inputting terminal of a shift register unit of a next stage of the adjacent two shift register units; the shift register unit of the next stage has its first scanning pulse outputting terminal connected to the second scanning pulse inputting terminal of the shift register unit of the previous stage; each of shift register units of odd-numbered stage of the plurality of the cascaded shift register units has the first clock signal terminal connected to a first clock signal line, the second clock signal terminal connected to a second clock signal line, and the third clock signal terminal connected to a third clock signal line; and each of the shift register units of even-numbered stage of the plurality of the cascaded shift register units has the first clock signal terminal connected to the third clock signal line, the second clock signal terminal connected to a fourth clock signal line, and the third clock signal terminal connected to the first clock signal line.

### BRIEF DESCRIPTION OF THE DRAWINGS

In order to describe solutions of the embodiments of the present disclosure more clearly, the accompanying drawings will be described briefly hereinafter. It should be noted that the accompanying drawings in the following description only relate to some embodiments of the present disclosure, but not to limiting the present disclosure, in which:

FIG. 1 shows a schematic structural diagram of a shift register unit according to an embodiment of the present disclosure;

FIG. 2 shows a gate driving circuit GOA including the shift register unit according to an embodiment of the present disclosure;

FIG. 3 shows a driving method of the gate driving circuit according to an embodiment of the present disclosure;

FIG. 4 shows a schematic structural diagram of a shift register unit according to another embodiment;

FIG. 5A and FIG. 5B shown circuit schematic diagrams of shift register units according to other embodiments of the disclosure respectively.

### DETAILED DESCRIPTION

In order to understand the above objects, features and advantages of the present disclosure clearly, the present disclosure will be further described in detail below with reference to the accompanying drawings and specific embodiments. It should be noted that the embodiments of the present application and the features in the embodiments may be combined with each other without conflicting.

In the following description, a number of specific details are set forth in order to provide a thorough understanding of the present invention. However, the present invention can also be implemented in other ways different from those described herein. Therefore, the scope of the present invention is not limited to the specific embodiments disclosed below.

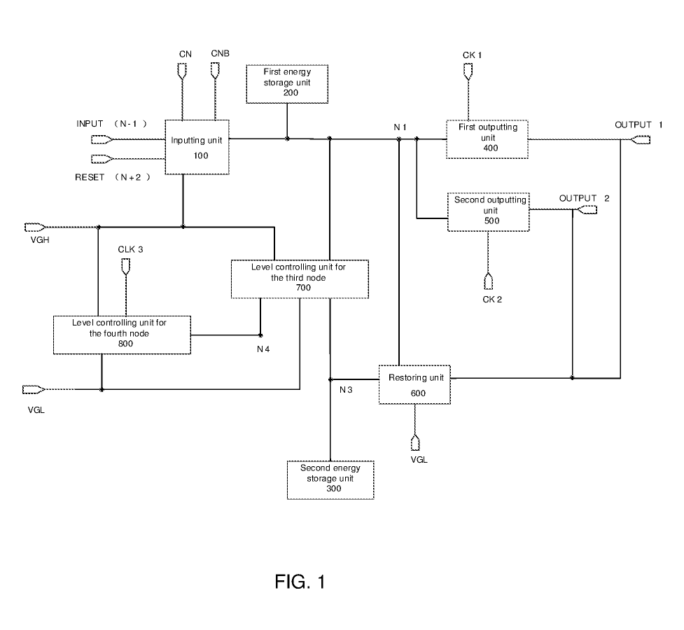

FIG. 1 shows a schematic structural diagram of a shift register unit according to an embodiment of the present disclosure. As shown in FIG. 1, the shift register unit according to the embodiment of the present disclosure may include: an inputting sub-circuit 100, electrically connected to a first DC voltage terminal CN, a second DC voltage terminal CNB, a third DC voltage terminal VGH, a first scanning pulse inputting terminal INPUT, a second scanning pulse inputting terminal RESETTING and a first node N1. It can be configured to conduct the first node N1 to the first DC voltage terminal CN, in response to the first scanning pulse inputting terminal INPUT being at the first level; and to conduct the first node N1 and the second DC voltage terminal CNB, in response to the second scanning pulse inputting terminal RESETTING being at the first level. The shift register unit may further include a first energy storage sub-circuit 200, which is electrically connected to the first node N1 and configured to maintain the charge of the first node N1 when the first node N1 is floating; a second energy storage sub-circuit 300, which is electrically connected to the third node N3 and configured to maintain the charge of the third node N3 when the third node N3 is floating; a first outputting sub-circuit 400, which is electrically connected to the first node N1, a first clock signal terminal CK1 and a first scanning pulse outputting terminal OUTPUT1 and configured to conduct the first scanning pulse outputting terminal OUTPUT1 with the first clock signal terminal CK1 in response to the first node N1 being at the first level; a second outputting sub-circuit 500, which is electrically connected to the first node N1, a second clock signal terminal CK2 and the second scanning pulse outputting terminal OUTPUT2 and configured to conduct the second scanning pulse outputting terminal OUTPUT2 and the second clock signal terminal CK2 in response to the first node N1 being at the first level; a restoring sub-circuit 600, electrically connected to the first node N1, the third node N3, a fourth DC voltage terminal VGL, a first scanning pulse outputting terminal OUTPUT1 and the second scanning pulse outputting terminal OUTPUT2, and configured to conduct the first node N1, the first scanning pulse outputting terminal OUTPUT1, the second scanning pulse outputting terminal OUTPUT2 and the fourth DC voltage terminal VGL in response to the third node N3 being at the first level; a level controlling sub-circuit for the third node 700, electrically connected to the third DC voltage terminal VGH, the fourth DC voltage terminal VGL, the first node N1, the third node N3, and a fourth node N4, and configured to conduct the third node N3 with the third DC voltage terminal VGH in response to the fourth node N4 being at the first level, and to conduct the third node N3 with the fourth DC voltage terminal VGL in response to the first node N1 being at the first level; and a level controlling sub-circuit for the fourth node 800, which is electrically connected to the first DC voltage terminal CN, the second DC voltage terminal CNB, a third clock signal terminal CLK3 and the fourth node N4, and configured to conduct the fourth node N4 with the third clock signal terminal CLK3 in response to the first DC voltage terminal CN being the first level, and to conduct the fourth node N4 with the third clock signal terminal CLK3 in response to the second DC voltage terminal CNB being the first level.

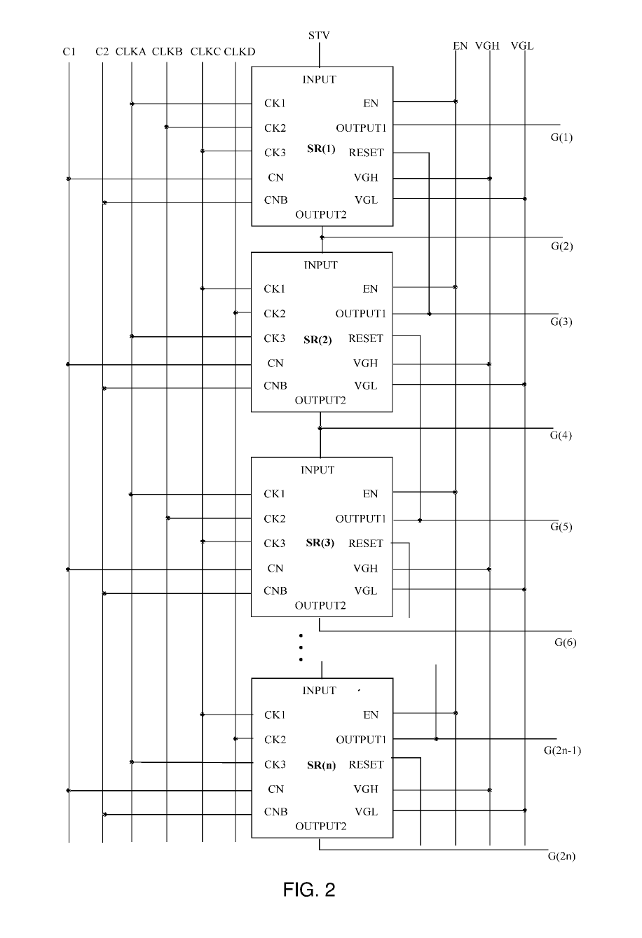

A gate driving circuit GOA including the shift register unit in FIG. 1 is provided with reference to FIG. 2. The gate driving circuit GOA includes a plurality of cascaded shift register units and a plurality of clock signal lines. Each of the cascaded shift register units may be the shift register unit described in the first aspect. For the adjacent two shift register units, the shift register unit SR(N) of a previous stage has its second scanning pulse outputting terminal OUTPUT2 (N) connected to the first scanning pulse inputting terminal INPUT (N+1) of a shift register unit SR(N+1) of the next stage; the shift register unit SR(N+1) of the next stage has its first scanning pulse outputting terminal OUTPUT2 (N+1) connected to the second scanning pulse inputting terminal RESETTING(N) of the shift register unit of the previous stage. The shift register units SR(2N+1) of odd-numbered stage of the plurality of the cascaded shift register units has the first clock signal terminal CK1 connected to a first clock signal line CLKA, the second clock signal terminal CK2 connected to a second clock signal line CLKB, and the third clock signal terminal CK3 connected to a third clock signal line CLKC. The shift register units SR(2N) of even-numbered stage of the plurality of the cascaded shift register units has the first clock signal terminal CK1 connected to the third clock signal line CLKC, the second clock signal terminal CK2 is connected to a fourth clock signal line CLKD, and the third clock signal terminal CK3 is connected to the first clock signal Line CLKA.

According to the embodiment of the present disclosure, when the first scanning pulse inputting terminal INPUT is at the first level, the first node N1 is conducted with the first DC voltage terminal CN, and the voltage at the first node N1 is pulled up by the first DC voltage terminal CN to achieve a forward scanning. When the second scanning pulse inputting terminal RESETTING is at the first level, the first node N1 is conducted with the second DC voltage terminal CNB, and the voltage at the first node N1 is pulled up by the second DC voltage terminal CNB to achieve a reverse scanning. Thus, the shift register according to the present disclosure can enable a bidirectional scanning of gate lines. In addition, each stage of shift register unit according to the present disclosure has two scanning pulse outputting terminals. The first scanning pulse outputting terminal OUTPUT1 of a Nth stage of shift register unit outputs a gate driving signal to a Nth stage of pixel unit, such that the second scanning pulse outputting terminal OUTPUT1 of the Nth stage of shift register unit may output a gate voltage to the (N+1)th row of pixel units during a next period after the Nth row of pixel units are turned on. Therefore, two rows of pixels can be controlled by only one stage of the shift register unit, which can improve the flexibility for displaying, and thus the display panel driven by the gate driving circuit including the shift register unit can meet various display requirements.

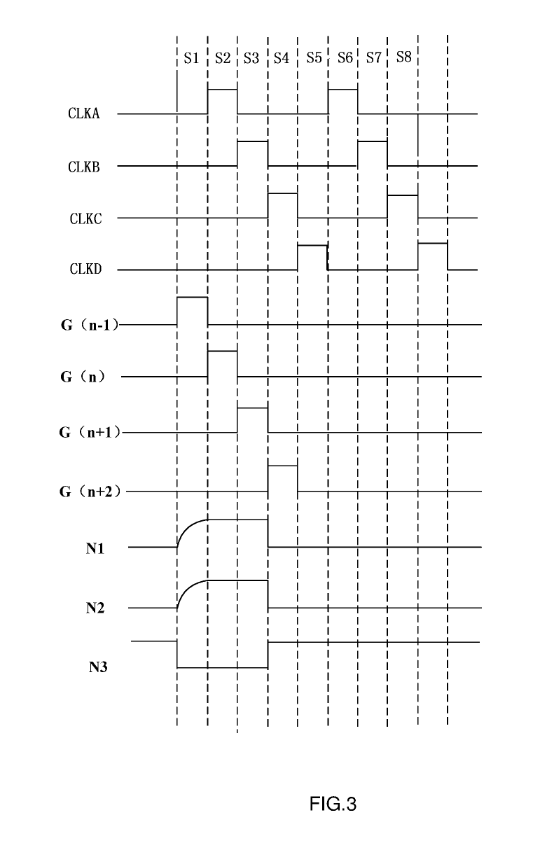

A driving method of the gate driving circuit shown in FIG. 2 and a principle of realizing the functions of the gate driving circuit shown in FIG. 2 are described below with reference to FIG. 3. Referring to FIG. 3, it is assumed that the first level here is a high level and the corresponding second level is a low level. In particular, the method may include:

inputting a first level DC voltage at a third DC voltage terminal VGH of each shift register unit;

inputting a second level DC voltage at the fourth DC voltage terminal VGL of each shift register unit;

inputting the first level DC voltage to the first DC voltage terminal CN of each shift register unit and the second level DC voltage to a second DC voltage terminal CNB of each shift register unit, when the gate driving circuit is operated in a forward scanning;

inputting the second level DC voltage to the first DC voltage terminal CN of each shift register unit and the first level DC voltage to the second DC voltage terminal CNB of each shift register unit, when the gate driving circuit is operated in a reverse scanning;

inputting a first clock signal CLKA to the first clock signal line CLKA (for the convenience of description, the clock signal inputted to each driving line is denoted by the same symbol as the driving line), a second clock signal CLKB to the second clock signal line CLKB, a third clock signal CLKC to the third clock signal line CLKC and a fourth clock signal CLKD to the fourth clock signal line CLKD;

inputting a starting scanning pulse STV to the scanning pulse inputting terminal INPUT of the first stage of shift register unit SR(1), wherein the starting scanning pulse STV is at a first level,

wherein the first clock signal CLKA, the second clock signal CLKB, the third clock signal CLKC and the fourth clock signal CLKD have the same cycle, and wherein the duty cycles of the first clock signal CLKA, the second clock signal CLK2, the third clock signal CLKB and the fourth clock signal CLK4 may be equal to ¼, and sequentially differ by ¼ cycle, and

wherein the starting scanning pulse STV has a starting time as the same as a starting time of one of the first levels of the first clock signal CLKD, and an ending time is the same as an ending time of the first level.

When the gate driving circuit performs the forward scanning, the first DC voltage terminal CN is at the first level and the second DC voltage terminal CNB is at the second level.

Referring to FIG. 3, for the first stage of shift register unit SR(1), in a first period S1, CLKA, CLKB, CLKC, and CLKD are all at the second level, while the starting scanning pulse STV is at the first level (the signal of the starting scanning pulse STV can refer to an outputting signal of (N−1)th stage in FIG. 3, and for the Nth stage of shift register unit SR(n), the outputting signal from the (N−1)th stage of shift register unit SR(n−1) corresponds to the starting signal). At this time, the inputting sub-circuit 100 conducts the first node N1 and the first DC voltage terminal CN, and the first node N1 is set to the first level. Thus, the first scanning pulse outputting terminal OUTPUT1 is conducted with the first clock signal terminal CK1 by the first outputting sub-circuit 400, and the second scanning pulse outputting terminal OUTPUT2 is conducted with the second clock signal terminal CK2 by the second outputting sub-circuit 500. Since the first clock signal line CLKA connected to the first clock signal terminal CK1 and the first clock signal line CLKB connected to the second clock signal terminal CK2 are both at the second level, the first scanning pulse inputting terminal OUTPUT1 and the second scanning pulse outputting terminal OUTPUT2 are both at the second level. In addition, since the first scanning pulse outputting terminal OUTPUT1 of the second stage of shift register unit SR(2) connected to the second scanning pulse inputting terminal RESETTING of the first stage of shift register unit SR(1) is at the second level, the second scanning pulse inputting terminal RESETTING of the first stage of shift register unit SR(1) is also at the second level. In addition, for the first stage of shift register unit SR(1), since it is currently in the forward scanning period, the first DC voltage terminal CN is at the first level. At this time, the level controlling sub-circuit for the fourth node 800 conducts the fourth node N4 with the third clock signal terminal CK3. During this period, the third clock signal line CLKC is at the second level, therefore, the fourth node N4 is also at the second level. The fourth node N4 does not affect the level controlling sub-circuit for the third node 700 at this period. At this time, the level controlling sub-circuit for the third node 700 is only affected by the first node N1. Since the first node N1 is at the first level, the level controlling sub-circuit for the third node 700 conducts the third node N3 with the fourth DC voltage terminal VGL, and sets the third node N3 as the second level. Since the third node N3 is at the second level, the restoring sub-circuit does not connect the first node N1, the first scanning pulse outputting terminal OUTPUT1, the second scanning pulse outputting terminal and the fourth DC voltage terminal VGL. At this period, the end of the first energy storage sub-circuit 200 which is connected to the first node N1 is written by a voltage.

Referring to FIG. 3 again, for the first stage of shift register unit SR(1), in a second period S2, the first node N1 keeps in being at the first level with the support of the first energy storage sub-circuit 200, the first clock signal terminal CK1 keeps in being conducted with the first scanning pulse outputting terminal OUTPUT1, the second clock signal terminal CK2 keeps in being conducted with the second scanning pulse outputting terminal OUTPUT2. In addition, the first clock signal line CLKA is at the first level, and the second clock signal line CLKB is at the second level. Accordingly, the first clock signal terminal CK1 is at a first level, and the second clock signal terminal CK2 is at a second level. This arrangement enables the first scanning pulse outputting terminal OUTPUT1 to start outputting scanning pulses of first level to the first row of pixel units G(1) and the second scanning pulse outputting terminal OUTPUT2 not to output. In addition, in the first stage of shift register unit SR(1), the second scanning pulse inputting terminal RESETTING keeps in being at the second level, the third node N3 also keeps in being at the second level, and the fourth node N4 is maintained at the second level further.

In the second period S2, for the second stage of shift register unit SR(2), signals inputted into each terminal (including the two clock signal terminals CK1 and CK2, the scanning pulse inputting terminal INPUT and the second scanning pulse inputting terminal RESETTING) is consistent with those of the first stage of shift register unit SR(1) in the first period S1. Therefore, the potentials of the respective nodes and the scanning pulse outputting terminal of the second stage of shift register unit SR(2) are as same as those of the first stage of shift register SR(1) in the first period S1, and thus will not be described in detail here.

In the third period S3, for the first stage of shift register unit SR(1), its second scanning pulse inputting terminal RESETTING is connected to the first scanning pulse outputting terminal OUTPUT1 of the second stage of shift register unit SR(2) which is at the second level (i.e. the signal outputted to the third row of pixel units). In this case, the first scanning pulse inputting terminal INPUT is also at the second level. Therefore, the first node N1 is neither conducted with the first DC voltage terminal CN nor the second DC voltage terminal CNB. The first node N1 is maintained at the first level with the support of the first energy storage sub-circuit 200. At this time, the first scanning pulse outputting terminal OUTPUT1 is conducted with the first clock signal terminal CK1 by the first outputting sub-circuit 400, and the second scanning pulse outputting terminal OUTPUT2 is conducted with the second clock signal terminal CK2 by the second outputting sub-circuit 500. However, during this period, the first clock signal line CLKA is at the second level and the second clock signal line CLKB is at the first level. Accordingly, the first clock signal terminal CK1 is at the second level, and the second clock signal terminal CK2 is at the first level. Therefore, the first scanning pulse outputting terminal OUTPUT1 does not output at this moment, and the second scanning pulse outputting terminal OUTPUT2 outputs the pulse signal of the first level to the second row of pixel unit G(2). In addition, for the first stage of shift register unit SR(1), since the first node N1 is at the first level during this period, the level controlling sub-circuit for the third node 700 may conduct the third node N3 with the fourth DC voltage terminal VGL. Thus, the third node N3 is set to be at the second level. At this time, the fourth node N4 is conducted with the third clock signal terminal CK3. During this period, the third clock signal line CLKC is at the second level. Accordingly, the third clock signal terminal CK3 is also at the second level, and the fourth node N4 is also set to the second level.

In the third period S3, for the second stage of shift register unit SR(2), signals inputted into each terminals (including the two clock signal terminals CK1 and CK2, the scanning pulse inputting terminal INPUT and the second scanning pulse inputting terminal RESETTING) is consistent with those of the first stage of shift register unit SR(1) in the second period S2. In other words, the first scanning pulse outputting terminal OUTPUT1 of the second stage of shift register unit SR(2) outputs scanning pluses to the third row of pixel units G(3), and the second scanning pulse outputting terminal OUTPUT2 of the second stage of shift register unit SR(2) does not output at this time. Therefore, the potentials of the respective nodes and the scanning pulse outputting terminal of the second stage of shift register unit SR(2) are as same as those of the first stage of shift register SR(1) in the second period S2, and thus will not be described in detail here.

In the fourth period S4, for the first stage of shift register unit SR(1), its second scanning pulse inputting terminal RESETTING is connected to the first scanning pulse outputting terminal OUTPUT1 of the second stage of shift register unit SR(2) which is at the first level (i.e. the signal outputted to the third row of pixel units). In this case, the second scanning pulse inputting terminal RESETTING is also at the first level. Therefore, the inputting sub-circuit 100 conducts the first node N1 with the second DC voltage terminal CNB. Since the forward scanning is performed at this time, the second DC voltage terminal CNB is at the second level, and thus the first node N1 is set to the first level. Therefore, the first clock signal terminal CK1 is not conducted with the first scanning pulse outputting terminal OUTPUT1, and the second clock signal terminal CK2 is not conducted with the second clock signal terminal CK2. Thus, the first scanning pulse outputting terminal OUTPUT1 and the second scanning pulse outputting terminal OUTPUT2 do not output. In addition, since the first DC voltage terminal of the first stage of shift register unit SR(1) is at a high level, the fourth node is conducted with the third clock signal terminal CK3. At this period, the third clock signal line CLKC connected to the third clock signal terminal CK3 is at the first level, and thus the fourth node is set to the first level. Accordingly, the level controlling sub-circuit for the third node 700 conducts the third node N3 with the third DC voltage terminal VGH, and the third node N3 is set to the first level. Therefore, the restoring sub-circuit 600 may conduct the first node N1, the first scanning pulse outputting terminal OUTPUT1, the second scanning pulse outputting terminal OUTPUT2 and the fourth DC voltage terminal VGL, and may set the first node N1, the first scanning pulse outputting terminal OUTPUT1 and the second scanning pulse outputting terminal OUTPUT2 to the second level in order to achieve restoring.

In the fourth period S4, for the second stage of shift register unit SR(2), signals inputted into each terminal (including the two clock signal terminals CK1 and CK2, the scanning pulse inputting terminal INPUT and the second scanning pulse inputting terminal RESETTING) is consistent with those of the first stage of shift register unit SR(1) in the third period S3. In other words, the second scanning pulse outputting terminal OUTPUT2 of the second stage of shift register unit SR(2) outputs scanning pluses to the fourth row of pixel units G(4), and the first scanning pulse outputting terminal OUTPUT1 of the second stage of shift register unit SR(2) does not output during this period. Therefore, the potentials of the respective nodes and the scanning pulse outputting terminal of the second stage of shift register unit SR(2) are as same as those of the first stage of shift register SR(1) in the third period S3, and thus will not be described in detail here.

It can be easily seen from the above driving process that for the two adjacent stages of shift register units, the signals received by each terminal of the latter stage of shift register unit in the current period have the same status as the signals received by each terminal of the previous stage of shift register unit in the lase period. Thus, it can be known that each stage of the shift register unit will output a plurality of scanning pulses sequentially.

It should be noted that the above scanning process is a forward scanning process, that is, the first scanning pulse inputting terminal INPUT is used as the inputting terminal for each stage of shift register unit, and the second scanning pulse inputting terminal RESETTING is used as a restoring terminal for each stage of shift register unit. It is not difficult to understand that the functions of these two terminals for using in a reverse scanning process are opposite to those in the forward scanning process. That is, the first scanning pulse inputting terminal INPUT will be used as the restoring terminal for each stage of shift register unit, and the second scanning pulse inputting terminal RESETTING will be used as an inputting terminal for each stage of shift register unit. The functional principles, potentials and outputting status of remaining terminals are the same as those in the forward scanning process, and thus will not described in detail here.

It should also be noted that the above-mentioned driving method is only one possible driving method of the gate driving circuit provided in FIG. 2. In practical, the driving method is not limited to the method shown in FIG. 3.

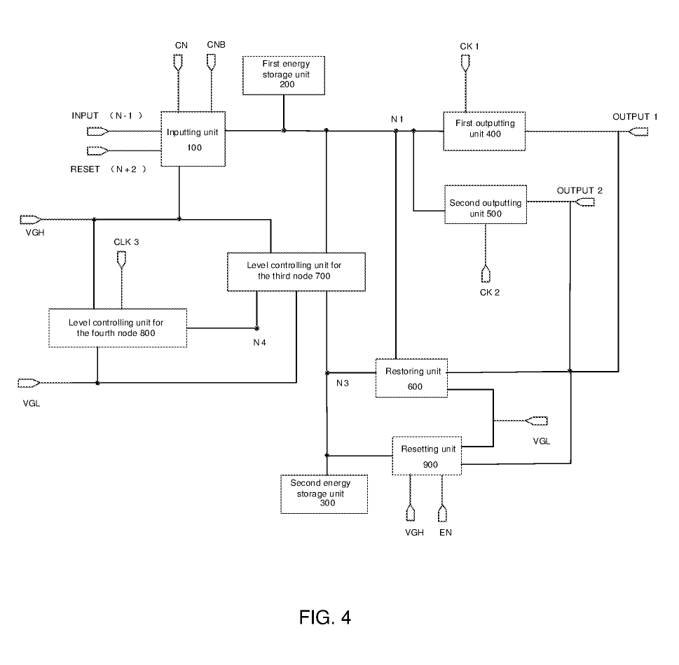

In specific implementation, the shift register unit according to the embodiment of the present disclosure may further include other structures than the basic structure shown by the shift register unit shown in FIG. 1. FIG. 4 shows a schematic structural diagram of a shift register unit according to another embodiment. In addition to the various sub-circuits shown in FIG. 1, the shift register unit in FIG. 4 further includes a resetting sub-circuit 900.

As shown in FIG. 4, the resetting sub-circuit 900 is connected to the third node N3, the resetting enable controlling terminal EN, the third DC voltage terminal VGH, the fourth DC voltage terminal VGL, the first scanning pulse outputting terminal OUTPUT1 and the second scanning pulse outputting terminal OUTPUT2, and configured to conduct the third node N3 with the fourth DC voltage terminal VGL and to conduct the first scanning pulse outputting terminal OUTPUT1 and the second scanning pulse outputting terminal OUTPUT2 with the third DC voltage terminal VGH, in response to the resetting enable controlling terminal EN being at the first level.

In the following, a driving method of the gate driving circuit in FIG. 4 and its working principle are described. It is also assumed that the first level is a high level and the second level is a low level. It can be understood that the process of the gate driving circuit including the shift register unit according to the present embodiment performing a forward or reverse scanning is the same as the process in the previous embodiment, except that a resetting enable signal EN is input to the resetting enable controlling terminal EN of each shift register unit. The resetting enable signal EN keeps in being at the second level during the scanning of the gate driving circuit of each frame, and changes into the first level after the scanning of each frame is completed. Therefore, after the scanning of each frame is completed, the resetting enable signal terminal EN is at the first level. The resetting sub-circuit 900 conducts the third node N3 and the fourth DC voltage terminal VGL and sets the third node N3 to the second level. Therefore, the resetting sub-circuit 900 has on effect on respective scanning pulse outputting terminal. Meanwhile, the resetting sub-circuit 900 conducts the first scanning pulse outputting terminal OUTPUT1 and the second scanning pulse outputting terminal OUTPUT2 with the third DC voltage terminal VGH, and sets the first scanning pulse outputting terminal OUTPUT1 and the second scanning pulse outputting terminal OUTPUT2 to the first level, so that the signals of the first scanning pulse outputting terminal OUTPUT1 and the second scanning pulse outputting terminal OUTPUT2 are erased and reset.

According to the embodiment of the present disclosure, since the resetting sub-circuit 900 of each stage of shift register is connected to the resetting enable controlling terminal EN, after the scanning of each frame is completed, the first scanning pulse outputting terminals OUTPUT1 and the second scanning pulse outputting terminals OUTPUT2 of the stages of shift register units are all conducted with VGH under the control of the resetting enable controlling terminal EN, so that the output states of all of the shift register units can be erased and reset at a time, which facilitates in scanning of the next frame.

It can be seen from the above description that the designing of respective functional units will not limit the scope of the present disclosure as long as their corresponding functions can be implemented. Some exemplary implementations of the respective functional units are further described below.

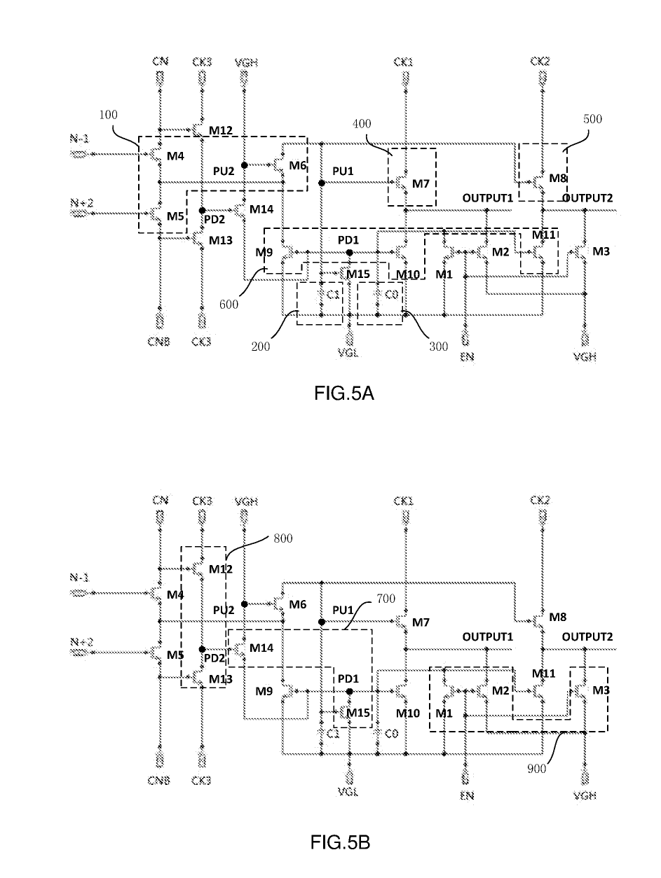

Referring to FIG. 5A, the inputting sub-circuit 100 includes a fourth transistor M4, a fifth transistor M5 and a transmission sub-circuit. The fourth transistor M4 has a gate connected to the first scanning pulse inputting terminal INPUT, one of a source and a drain connected to the first DC voltage terminal CN, and the other connected to the first node N1. The fifth transistor M5 has a gate connected to the second scanning pulse inputting terminal CNB, one of a source and a drain connected to the first DC voltage terminal CN, and the other connected to the first node N1. In addition, the transmission sub-circuit in the inputting sub-circuit 100 includes a sixth transistor M6 having a gate connected to the third DC voltage terminal VGH, one of a source and a drain connected to the second node N2, and the other connected to the first node N1.

The principle of the inputting sub-circuit 100 is as follows. Since the gate of the sixth transistor M6 in the transmission sub-circuit is connected to the third DC voltage terminal VGH, the sixth transistor M6 keeps in being in a turned-on state for a long time. The sixth transistor M6 can prevent the first node from leaking, thereby ensuring that no charge is drawn out from the first node. When performing the forward scanning, the first DC voltage terminal CN is at the first level and the second scanning pulse inputting terminal CNB is at the second level. When the first scanning pulse input terminal INPUT is at the first level, the fourth transistor M4 is turned on. At this time, the first node is conducted with the first DC voltage terminal CN by the sixth transistor M6 and the fourth transistor M4, thereby being set to the first level, so as to achieve the above-mentioned function of the inputting sub-circuit 100. When performing the reverse scanning, the first DC voltage terminal CN is at the second level and the second scanning pulse inputting terminal CNB is at the first level. When the second scanning pulse input terminal RESETTING is at the first level, the fifth transistor M5 is turned on. At this time, the first node is conducted with the second DC voltage terminal CNB by the sixth transistor M6 and the fifth transistor M5, thereby being set to the first level, so as to achieve the above-mentioned function of the inputting sub-circuit 100.

In specific implementation, referring to FIG. 5A, the first outputting sub-circuit 400 includes a seventh transistor M7 having a gate connected to the first node N1, one of the source and the drain connected to the first scanning pulse outputting terminal OUTPUT1, and the other connected to the first clock signal terminal CK1. Alternatively or additionally, the second outputting sub-circuit 500 includes an eighth transistor M8 having a gate connected to the first node N1, one of the source and the drain connected to the second scanning pulse outputting terminal OUTPUT2, and the other connected to the second clock signal terminal CK2.

The principle of the first outputting sub-circuit 400 is as follows: in response to the first node being at the first level, turning on the seventh transistor M7, so as to conduct the first scanning pulse outputting terminal OUTPUT1 and the first clock signal terminal CK1, such that the first scanning pulse outputting terminal OUTPUT1 outputs a scanning pulse of the same waveform as the first clock signal terminal CK1. The principle of the second outputting sub-circuit 500 is as follows: in response to the first node being at the first level, turning on the eighth transistor M8 so as to conduct the second scanning pulse outputting terminal OUTPUT2 and the second clock signal terminal CK2, such that the second scanning pulse outputting terminal OUTPUT2 outputs a scanning pulse of the same waveform as the second clock signal terminal CK2. In the above manner, the functions of the first outputting sub-circuit 400 and the second outputting sub-circuit 500 are realized.

In specific implementation, referring to FIG. 5A, the first energy storage sub-circuit 200 includes a first capacitor C1 having one terminal connected to the first node N1 and the other connected to the fourth DC voltage end VGL. Alternatively or additionally, the second energy storage sub-circuit 300 includes a second capacitor C0 having one terminal connected to the third node N3 and the other connected to the fourth DC voltage end VGL.

The first energy storage sub-circuit 200 and the second energy storage sub-circuit 300 have the same functions and are used to maintain the charge of the first node N1 or the third node N3 when the first node N1 or the third node N3 is floating, thereby making the first node N1 or the third node N3 being at the current level state.

Referring to FIG. 5A, the restoring sub-circuit 600 may include a ninth transistor M9, a tenth transistor M10, and an eleventh transistor M11. The ninth transistor M9 may have a gate connected to the third node N3, one of the source and the drain connected to the first node N1, and the other connected to the fourth DC voltage terminal VGL. The tenth transistor M10 may have a gate connected to the third node N3, one of the source and the drain connected to the first scanning pulse outputting terminal OUTPUT1, and the other connected to the fourth DC voltage terminal VGL. The eleventh transistor M11 may have its gate connected to the third node N3, one of the source and the drain connected to the second scanning pulse outputting terminal OUTPUT2, and the other connected to the fourth DC voltage terminal VGL.

The principle of the restoring sub-circuit 600 is specifically as follows: when the third node N3 is at the first level, the ninth transistor M9, the tenth transistor M10 and the eleventh transistor M11 are all turned on. At this time, the first node N1 is conducted with the fourth DC voltage terminal VGL by the ninth transistor M9, so as to be set to the second level. The first scanning pulse outputting terminal OUTPUT1 is conducted with the fourth DC voltage terminal VGL by the tenth transistor M10, and thus set to the second level. The second scanning pulse outputting terminal OUTPUT2 is conducted with the fourth DC voltage terminal VGL by the eleventh transistor M11, and thus set to the second level. Therefore, the function of resetting the first node N1, the first scanning pulse outputting terminal OUTPUT1 and the second scanning pulse outputting terminal OUTPUT2 can be achieved.

Referring to FIG. 5B, the level controlling sub-circuit for the third node 700 includes a fourteenth transistor M14 and a fifteenth transistor M15. The fourteenth transistor M14 has its gate connected to the fourth node N4, one of the source and the drain connected to the third DC voltage terminal VGH, and the other connected to the third node N3. The fifteenth transistor M15 has its gate connected to the first node N1, one of the source and the drain connected to the fourth DC voltage terminal VGL, and the other connected to the third node N3.

The principle of the level controlling sub-circuit for the third node 700 is as follows. In response to the fourth node being at the first level, the fourteenth transistor M14 is turned on, and the third node N3 is conducted with the third DC voltage terminal VGH by the fourteenth transistor M14, so as to be set to the first level. In response to the first node being at the first level, the fifteenth transistor M15 is turned on, and the third node N3 is conducted with the fourth DC voltage terminal VGL by the fifteenth transistor M15, so as to be set to the second level. Thus, the capability of controlling the level of the third node N3 (i.e the function of the level controlling sub-circuit for the third node 700) can be achieved.

In specific implementation, referring to FIG. 5B, the level controlling sub-circuit for the fourth node 800 includes a twelfth transistor M12 and a thirteenth transistor M13. The twelfth transistor M12 has its gate connected to the first DC voltage terminal CN, one of the source and the drain connected to the third clock signal terminal CK3, and the other connected to the fourth node N4. The thirteenth transistor M13 has its gate connected to the second DC voltage terminal CNB, one of the source and the drain connected to the third clock signal terminal CK3, and the other connected to the fourth node N4.

The principle of the level controlling sub-circuit for the fourth node 800 is as follows. When the gate driving circuit performs a forward scanning on the gate lines, the first DC voltage terminal CN is at the first level and the second DC voltage terminal CNB is at the second level. At this time, the twelfth transistor M12 is turned on to conduct the fourth node N4 with the third clock signal terminal CK3, thereby outputting the same pulse signal as the third clock signal terminal CK3. When the gate driving circuit performs a reverse scanning on the gate lines, the first DC voltage terminal CN is at the second level and the second DC voltage terminal CNB is at the first level. At this time, the thirteenth transistor M13 is turned on, so as to conduct the fourth node N4 with the third clock signal terminal CK3. Thus, the same pulse signal as the third clock signal terminal CK3 is outputted. Thereby, the function of the level controlling sub-circuit for the fourth node 800 can be achieved.

Referring to FIG. 5B, the resetting sub-circuit 900 includes a first transistor M1, a second transistor M2, and a third transistor M3. The first transistor M1 has its gate connected to the resetting enable controlling terminal EN, one of the source and the drain connected to the fourth DC voltage terminal VGL, and the other connected to the third node N3. The second transistor M2 has its gate connected to the resetting enable controlling terminal EN, one of the source and the drain connected to the third DC voltage terminal VGH, and the other connected to the first scanning pulse outputting terminal OUTPUT1. The third transistor M3 has its gate connected to the resetting enable controlling terminal EN, one of the source and the drain connected to the third DC voltage terminal VGH, and the other connected to the second scanning pulse outputting terminal OUTPUT2.

The principle of the resetting sub-circuit 800 is as follows. When the resetting enable controlling terminal EN is at the first level, the first transistor M1, the second transistor M2 and the third transistor M3 are all turned on. At this time, the third node is conducted with the fourth DC voltage terminal VGL by the first transistor M1 and thus set to a second level, such that the third node N3 no longer affects the signal states of the first scanning pulse outputting terminal OUTPUT1 and the second scanning pulse outputting terminal OUTPUT2. The first scanning pulse outputting terminal OUTPUT1 is conducted with the third DC voltage terminal VGH by the second transistor M2, so as to be set to the first level. Similarly, the second scanning pulse outputting terminal OUTPUT2 is connected with the third DC voltage terminal VGH by the third transistor M3, so as to be set to the first level. Thus, the first scanning pulse outputting terminal OUTPUT1 and the second scanning pulse outputting terminal OUTPUT2 are reset to prepare for scanning the next frame.

In the above example, the transistors included in each sub-circuit are transistors which can be turned on at the first level, wherein the first level may be a high level. This can be made by the same process, which can reduce the production difficulty.

In the description provided herein, numerous specific details are set forth. However, it is to be understood that the embodiments of the present invention may be practiced without these specific details. In some instances, well-known methods, structures, and techniques have not been shown in detail in order not to obscure the understanding of this description.

It should be understood that the above embodiments are merely intended for describing the technical solutions of the present invention other than limiting the present invention. Although the present invention is described in detail with reference to the foregoing embodiments, it should be understood by those of ordinary skill in the art that the various modifications and improvements may be made without departing from the spirit and essence of the present disclosure, and these variations and improvements are also considered as the scope of the present disclosure.

1. A shift register unit, comprising:
an inputting sub-circuit, electrically connected to a first DC voltage terminal, a second DC voltage terminal, a third DC voltage terminal, a first scanning pulse inputting terminal, a second scanning pulse inputting terminal and a first node, and configured to conduct the first node with the first DC voltage terminal in response to the first scanning pulse inputting terminal being a first level, and to conduct the first node with the second DC voltage terminal in response to the second scanning pulse inputting terminal being the first level;
a first energy storage sub-circuit, electrically connected to the first node and configured to maintain the charge of the first node when the first node is floating;
a second energy storage sub-circuit, electrically connected to a third node and configured to maintain the charge of the third node when the third node is floating;
a first outputting sub-circuit, electrically connected to the first node, a first clock signal terminal and a first scanning pulse outputting terminal, and configured to conduct the first scanning pulse outputting terminal with the first clock signal terminal in response to the first node being the first level;
a second outputting sub-circuit, electrically connected to the first node, a second clock signal terminal and a second scanning pulse outputting terminal, and configured to conduct the second scanning pulse outputting terminal with the second clock signal terminal in response to the first node being the first level;
a restoring sub-circuit, electrically connected to the first node, the third node, a fourth DC voltage terminal, the first scanning pulse outputting terminal and the second scanning pulse outputting terminal; and configured to conduct the first node, the first scanning pulse outputting terminal, the second scanning pulse outputting terminal and the fourth DC voltage terminal in response to the third node being at the first level;
a level controlling sub-circuit for the third node, electrically connected to the third DC voltage terminal, the fourth DC voltage terminal, the first node, the third node, and a fourth node, and configured to conduct the third node with the third DC voltage terminal in response to the fourth node being at the first level, and to conduct the third node with the fourth DC voltage terminal in response to the first node being at the first level; and
a level controlling sub-circuit for the fourth node, electrically connected to the first DC voltage terminal, the second DC voltage terminal, a third clock signal terminal and the fourth node, and configured to conduct the fourth node with the third clock signal terminal in response to the first DC voltage terminal being the first level, and to conduct the fourth node with the third clock signal terminal in response to the second DC voltage terminal being the first level.

2. The shift register unit of claim 1, further comprising:
a resetting sub-circuit, electrically connected to the third node, a resetting enable controlling terminal, the third DC voltage terminal, the fourth DC voltage terminal, the first scanning pulse outputting terminal and the second scanning pulse outputting terminal, and configured to conduct the third node with the fourth DC voltage terminal, and conduct the first scanning pulse outputting terminal and the second scanning pulse outputting terminal with the third DC voltage terminal, in response to the resetting enable controlling terminal being at the first level.

3. The shift register sub-circuit of claim 2, wherein the resetting unit comprises a first transistor, a second transistor, and a third transistor, and
the first transistor has a gate connected to the resetting enable controlling terminal, one of a source and a drain connected to the fourth DC voltage terminal, and the other connected to the third node;
the second transistor has a gate connected to the resetting enable controlling terminal, one of a source and a drain connected to the third DC voltage terminal, and the other connected to the first scanning pulse outputting terminal; and
the third transistor has a gate connected to the resetting enable controlling terminal, one of a source and a drain connected to the third DC voltage terminal, and the other connected to the second scanning pulse outputting terminal.

4. The shift register unit of claim 1, wherein the inputting sub-circuit comprises a fourth transistor, a fifth transistor and a transmission sub-circuit, and the fourth transistor has a gate connected to the first scanning pulse inputting terminal, one of a source and a drain connected to the first DC voltage terminal, and the other connected to the first node;
the fifth transistor has a gate connected to the second scanning pulse inputting terminal, one of a source and a drain connected to the first DC voltage terminal, and the other connected to the first node;
the transmission sub-circuit comprises a sixth transistor having a gate connected to the third DC voltage terminal, one of a source and a drain connected to the second node, and the other connected to the first node.

5. The shift register unit of claim 1, wherein
the first energy storage sub-circuit comprises a first capacitor having one terminal connected to the first node and the other connected to the fourth DC voltage terminal; and/or
the second energy storage sub-circuit comprises a second capacitor having one terminal connected to the third node and the other connected to the fourth DC voltage terminal.

6. The shift register unit of claim 1, wherein,
the first outputting sub-circuit comprises a seventh transistor having a gate connected to the first node, one of a source and a drain connected to the first scanning pulse outputting terminal, and the other connected to the first clock signal terminal; and/or,
the second outputting sub-circuit comprises an eighth transistor having a gate connected to the first node, one of a source and a drain connected to the second scanning pulse outputting terminal, and the other connected to the second clock signal terminal.

7. The shift register unit of claim 1, wherein the restoring sub-circuit comprises:
a ninth transistor, a tenth transistor and an eleventh transistor;
the ninth transistor has a gate connected to the third node, one of a source and a drain is connected to the first node, and the other connected to the fourth DC voltage terminal;
the tenth transistor has a gate connected to the third node, one of a source and a drain is connected to the first scanning pulse outputting terminal, and the other connected to the fourth DC voltage terminal; and
the eleventh transistor has a gate connected to the third node, one of a source and a drain connected to the second scanning pulse outputting terminal, and the other connected to the fourth DC voltage terminal.

8. The shift register unit of claim 1, wherein the level controlling sub-circuit for the third node comprises a fourteenth transistor and a fifteenth transistor, wherein,
the fourteenth transistor has a gate connected to the fourth node, one of a source and a drain connected to the third DC voltage terminal, and the other connected to the third node; and
the fifteenth transistor has a gate connected to the first node, one of a source and a drain connected to the fourth DC voltage terminal, and the other connected to the third node.

9. The shift register unit of claim 1, wherein the level controlling sub-circuit for the fourth node comprises a twelfth transistor and a thirteenth transistor, wherein,
the twelfth transistor has a gate connected to the first DC voltage terminal, one of a source and a drain connected to the third clock signal terminal, and the other connected to the fourth node; and
the thirteenth transistor has a gate connected to the second DC voltage terminal, one of a source and a drain connected to the third clock signal terminal, and the other connected to the fourth node.

10. The shift register unit of claim 1, wherein the first level is a high level.

11. A gate driving circuit, comprising a plurality of cascaded shift register units and a plurality of clock signal lines, wherein each of the plurality of the cascaded shift register units is the shift register unit of claim 1; and
wherein for shift register units in adjacent two stages of the plurality of cascaded shift register units, a shift register unit in a previous stage of the adjacent two shift register units has its second scanning pulse outputting terminal connected to the first scanning pulse inputting terminal of a shift register unit in a next stage of the adjacent two shift register units; the shift register unit in the next stage has its first scanning pulse outputting terminal connected to the second scanning pulse inputting terminal of the shift register unit in the previous stage; each of shift register units in odd-numbered stage of the plurality of the cascaded shift register units has the first clock signal terminal connected to a first clock signal line, the second clock signal terminal connected to a second clock signal line, and the third clock signal terminal connected to a third clock signal line; and each of the shift register units in even-numbered stage of the plurality of the cascaded shift register units has the first clock signal terminal connected to the third clock signal line, the second clock signal terminal connected to a fourth clock signal line, and the third clock signal terminal connected to the first clock signal line.
